(19) United States
(12) Patent Application Publication
(10) Pub. No.: US 2026/0157140 A1
(43) Pub. Date: Jun. 4, 2026

(54) SUBSTRATE PROCESSING DEVICE

(71) Applicant: Tokyo Electron Limited, Tokyo (JP)

(72) Inventors: Koei ITO, Miyagi (JP); Dai KITAGAWA, Miyagi (JP); Taisei SEGUCHI, Miyagi (JP)

(73) Assignee: Tokyo Electron Limited, Tokyo (JP)

(21) Appl. No.: 19/460,422

(22) Filed: Jan. 27, 2026

Related U.S. Application Data
(63) Continuation of application No. PCT/JP2024/026684, filed on Jul. 25, 2024.

(30) Foreign Application Priority Data
Aug. 4, 2023 (JP) 2023-127933

(51) Int. Cl. H10P 72/00

(52) U.S. Cl. CPC H10P 72/0462; H10P 72/0402

(57) ABSTRACT

A substrate processing device includes a first chamber and a second chamber. The second chamber includes a circulation space defined in a wall of the second chamber to allow a gas to circulate in a direction in which the wall extends, at least one supply port connecting with the circulation space to supply the gas, and at least one outlet connecting with the circulation space to discharge the gas to at least one of an inside or an outside of the second chamber.

### CROSS-REFERENCE TO RELATED APPLICATIONS

This application is a Continuation of PCT International Application No. PCT/JP2024/026684, filed on Jul. 25, 2024, which claims priority under 35 U.S.C. §119(a) to Patent Application No. JP2023-127933, filed in Japan on Aug. 4, 2023, all of which are hereby expressly incorporated by reference into the present application.

### FIELD

Exemplary embodiments of the disclosure relate to a substrate processing device.

### BACKGROUND

Patent Literature 1 describes a substrate processing device. The substrate processing device includes a first chamber, a movable unit movable vertically in the first chamber, and a second chamber held by the movable unit in the first chamber and defining a processing space together with the substrate support. The second chamber includes a ceiling extending above the processing space. The ceiling has multiple gas holes for supplying a gas to the processing space. The ceiling is in contact with the movable unit. The gas holes in the ceiling connect with the gas holes in the movable unit.

### Citation List

### Patent Literature

Patent Literature 1: Japanese Unexamined Patent Application Publication No. 2022-66828

### BRIEF SUMMARY

One or more aspects of the present disclosure are directed to a technique for allowing gas outlets to be arranged in a larger area in the radial direction of a chamber.

A substrate processing device according to one or more embodiments includes a first chamber and a second chamber. In the first chamber, a substrate support to receive a substrate is located. The second chamber is located in the first chamber. The second chamber defines, together with the substrate support, a processing space for processing the substrate received on the substrate support. The second chamber includes a circulation space defined in a wall of the second chamber to allow a gas to circulate in a direction in which the wall extends, at least one supply port connecting with the circulation space to supply the gas, and at least one outlet connecting with the circulation space to discharge the gas to at least one of an inside or an outside of the second chamber.

### Advantageous Effects

The technique according to one or more embodiments allows the gas outlets to be arranged in a larger area in the radial direction of the chamber.

### BRIEF DESCRIPTION OF THE DRAWINGS

FIG. 1 is a diagram of a substrate processing system according to one or more embodiments.

FIG. 2 is a schematic diagram of a transfer module in the substrate processing system according to one or more embodiments.

FIG. 3 is a schematic diagram of a substrate processing device according to one or more embodiments.

FIG. 4 is a partially enlarged cross-sectional view of the substrate processing device according to one or more embodiments.

FIG. 5 is a diagram of an inner wall of a second chamber in the substrate processing device according to one or more embodiments.

FIG. 6 is a partially enlarged cross-sectional view of a substrate processing device according to one or more embodiments.

FIG. 7 is a schematic diagram of supply ports in a second chamber in a substrate processing device according to one or more embodiments.

### DETAILED DESCRIPTION

One or more embodiments will now be described.

A substrate processing device according to one or more embodiments includes a first chamber and a second chamber. In the first chamber, a substrate support to receive a substrate is located. The second chamber is located in the first chamber. The second chamber defines, together with the substrate support, a processing space for processing the substrate received on the substrate support. The second chamber includes a circulation space, at least one supply port, and at least one outlet. The circulation space is defined in a wall of the second chamber to allow a gas to circulate in a direction in which the wall extends. The supply port connects with the circulation space to supply the gas. The outlet connects with the circulation space to discharge the gas to at least one of an inside or an outside of the second chamber.

In the substrate processing device, the gas supplied through the supply port passes through the circulation space in the wall of the second chamber and is discharged through the outlet. With the circulation space extending in the direction in which the wall extends, the outlet can be at any position in the wall. In this structure, the outlet can be set at any position independently of the position of the gas supply port. This allows the gas outlet to be located in a larger area in the radial direction of the chamber.

In one or more embodiments, the wall of the second chamber may include a ceiling facing the substrate support and a peripheral wall continuous with the ceiling and surrounding the substrate support. The circulation space may be divided into a first circulation space extending in the ceiling in a direction in which the ceiling extends and a second circulation space extending in the peripheral wall in a direction in which the peripheral wall extends. The supply port may include a first supply port connecting with the first circulation space and a second supply port connecting with the second circulation space. In this structure, the circulation space is divided into the first circulation space and the second circulation space. The first circulation space and the second circulation space can thus be supplied with gases having different flow rates.

In one or more embodiments, the first supply port and the second supply port are supplied with different gases. This structure allows the different gases to be discharged as intended to a space near the outlet in the ceiling and to a space near the outlet in the peripheral wall.

In one or more embodiments, the outlet includes a first outlet being open to the inside of the second chamber and a second outlet being open to the outside of the second chamber. In this structure, the gas discharged through the first outlet facing the inside of the second chamber can reduce deposit accumulated on the inner wall of the second chamber. The gas discharged from the second outlet facing the outside of the second chamber can reduce deposit accumulated on the inner wall of the first chamber.

In one or more embodiments, the peripheral wall has air vents connecting the inside and the outside of the second chamber. The air vents may be separated from the circulation space by partitions. The air vents are arranged in a staggered manner. The outlet is located between adjacent air vents of the air vents and faces the inside of the second chamber. In this structure, the gas discharged through the outlet moves along the inner wall of the second chamber before being discharged through the air vent to outside the second chamber. In this case, the gas may protect the inner wall of the second chamber as an air curtain.

In one or more embodiments, the substrate processing device may further include a movable unit (e.g., movable housing) that vertically moves the second chamber in the first chamber, and a bellows connected to the movable unit and separating a space in the first chamber from an outside of the first chamber. The gas is supplied to the supply port through inside a space defined by the bellows. This structure easily provides the path for supplying the gas.

One or more embodiments will now be described in detail with reference to the drawings. In the figures, like reference numerals denote like or corresponding components.

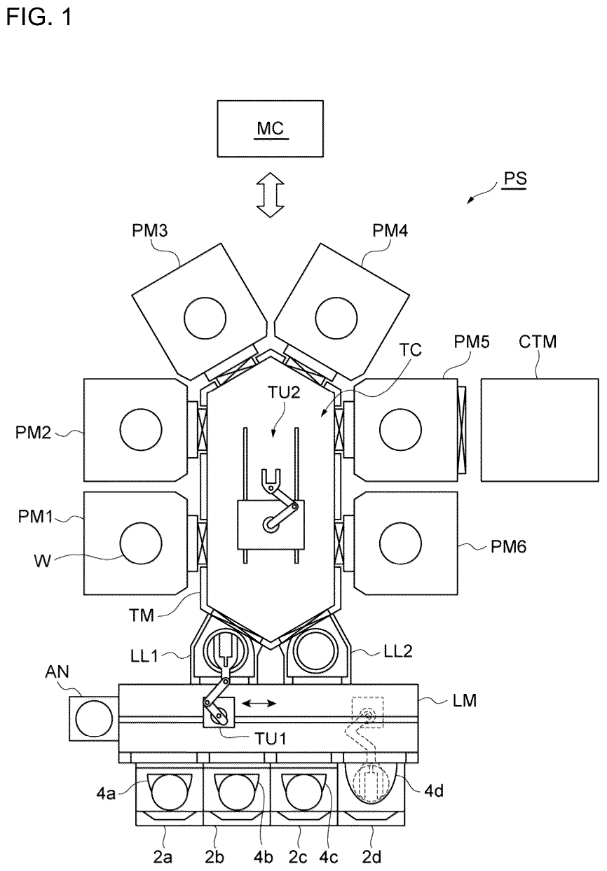

FIG. 1 is a diagram of a substrate processing system including an inner chamber according to one or more embodiments. A substrate processing system PS shown in FIG. 1 includes process modules PM1 to PM6, a transfer module CTM, and a controller MC.

The substrate processing system PS may further include tables 2a to 2d, containers 4a to 4d, an aligner AN, loadlock modules LL1 and LL2, and a transfer module TM. The substrate processing system PS may include one or more tables, one or more containers, and one or more loadlock modules. The substrate processing system PS may include one or more process modules.

The tables 2a to 2d are arranged along one edge of a loader module LM. The containers 4a to 4d are mounted on the respective tables 2a to 2d. The containers 4a to 4d are, for example, containers called front-opening unified pods (FOUPs). The containers 4a to 4d store substrates W.

The loader module LM includes a chamber. The chamber in the loader module LM has an atmospheric pressure. The loader module LM includes a transfer unit TU1. The transfer unit TU1 is, for example, a transfer robot controlled by the controller MC. The transfer unit TU1 transfers the substrate W through the chamber in the loader module LM. The transfer unit TU1 may transfer the substrate W between the containers 4a to 4d and the aligner AN, between the aligner AN and the loadlock modules LL1 and LL2, and between the loadlock modules LL1 and LL2 and the containers 4a to 4d. The aligner AN is connected to the loader module LM. The aligner AN adjusts (corrects) the position of the substrate W.

The loadlock modules LL1 and LL2 are located between the loader module LM and the transfer module TM. The loadlock modules LL1 and LL2 serve as preliminary decompression chambers. The loadlock modules LL1 and LL2 are connected to the loader module LM with gate valves. The loadlock modules LL1 and LL2 are connected to the transfer module TM with the gate valves.

The transfer module TM includes a decompressible transfer chamber TC. The transfer module TM includes a transfer unit TU2. The transfer unit TU2 is, for example, a transfer robot controlled by the controller MC (e.g., controller circuit). The transfer unit TU2 transfers the substrate W through the transfer chamber TC. The transfer unit TU2 may transfer the substrate W between the loadlock modules LL1 and LL2 and the process modules PM1 to PM6, and between any two of the process modules PM1 to PM6. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The process modules PM1 to PM6 are connected to the transfer module TM with gate valves. The process modules PM1 to PM6 are dedicated to intended substrate processing. At least one of the process modules PM1 to PM6 is a substrate processing device according to an exemplary embodiment (described later).

The transfer module CTM includes a chamber and a transfer unit. The transfer module CTM is controlled by the controller MC. The transfer module CTM includes the transfer unit. The transfer unit in the transfer module CTM transfers a second chamber located in a first chamber in the substrate processing device into the chamber in the transfer module CTM.

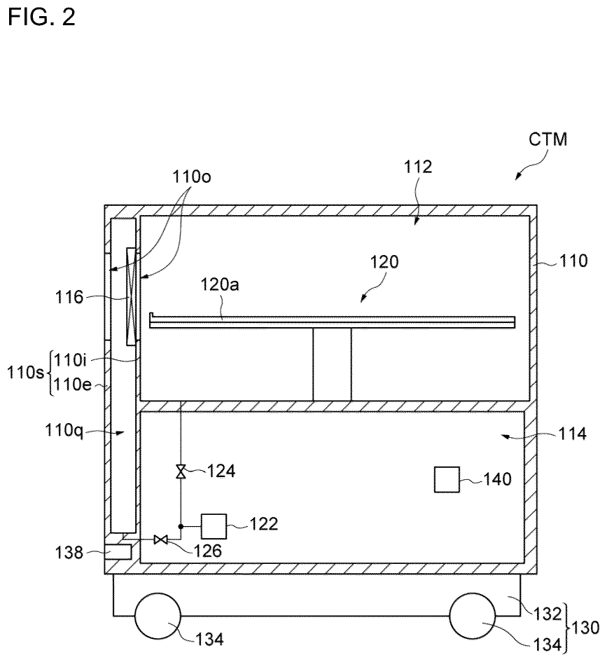

FIG. 2 is a schematic diagram of the transfer module in the substrate processing system according to one or more embodiments. The transfer module CTM includes a chamber 110. The chamber 110 has an internal space 112 and an internal space 114. The internal space 112 is located above the internal space 114 and separate from the internal space 114. The chamber 110 includes a side wall 110s having openings 110o continuous with the internal space 112. The openings 110o can be open and closed by a gate valve 116.

In one or more embodiments, the side wall 110s partially has a double structure including an inner side wall 110i and an outer side wall 110e. The inner side wall 110i and the outer side wall 110e define a space 110q between them. The openings 110o are located in the inner side wall 110i and the outer side wall 110e. The gate valve 116 extends along the inner side wall 110i to open and close the openings 110o.

The transfer module CTM further includes a transfer unit 120. The transfer unit 120 is a transfer robot and includes an arm 120a. The transfer unit 120 is located in the internal space 112.

The transfer module CTM further includes an exhaust device 122. The exhaust device 122 is located in the internal space 114. The exhaust device 122 is connected to the internal space 112 with a valve 124 and connected to the space 110q with a valve 126. The exhaust device 122 decompresses the internal space 112 and the space 110q.

The transfer module CTM further includes a mover 130. The mover 130 includes a body 132 and multiple wheels 134. The body 132 incorporates a power supply, such as a battery, a power source, and a steering assembly. The wheels 134 are rotatable by the power source in the body 132 to move the transfer module CTM in a direction controlled by the steering assembly in the body 132. The mover 130 for moving the transfer module CTM may have any structure, such as a walk-behind mover, other than the structure with wheels.

The transfer module CTM further includes a sensor 138 and a controller 140. The sensor 138 is installed on an outer wall of the chamber 110. The controller 140 is located in the internal space 114. The sensor 138 senses the surrounding environment of the transfer module CTM and outputs the sensing result to the controller 140. The sensor 138 is, for example, an image sensor and outputs an image of the surroundings of the transfer module CTM to the controller 140. The controller 140 (e.g., control circuit) may be a computer including a processor, a storage, such as a memory, and a communicator. The controller 140 controls the components of the transfer module CTM. The controller 140 controls the mover 130 using the sensing result from the sensor 138 and moves the transfer module CTM to connect the transfer module CTM to a substrate processing device 1. The controller 140 also controls the exhaust device 122 and the valves 124 and 126.

The controller MC controls the components of the substrate processing system PS. The controller MC may be a computer including a processor, a storage, an input device, and a display. The controller MC executes a control program stored in the storage to control the components of the substrate processing system PS based on recipe data stored in the storage.

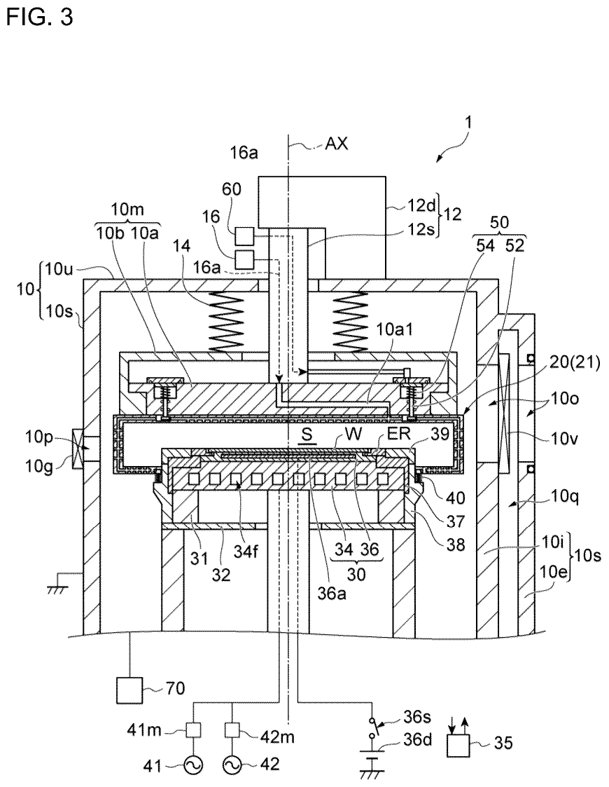

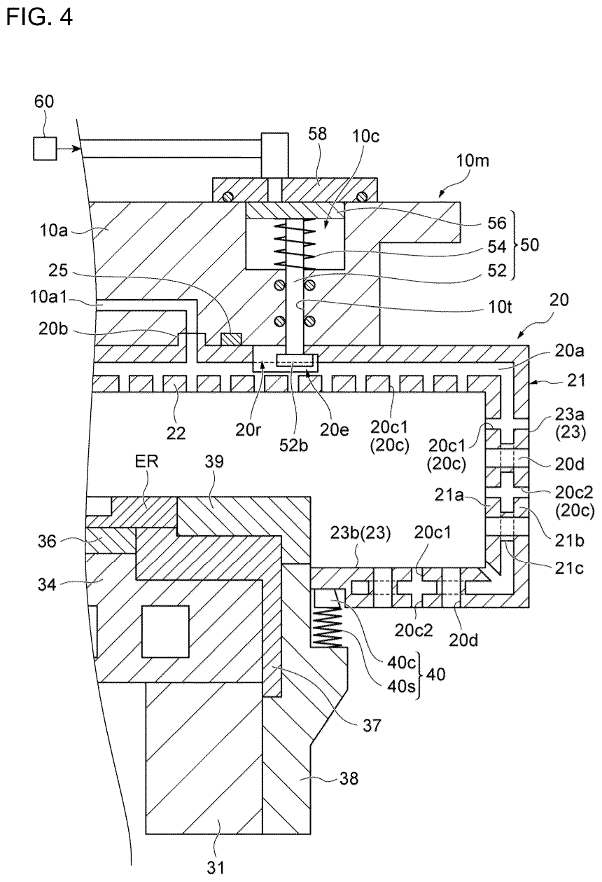

A substrate processing device according to an exemplary embodiment will now be described. FIG. 3 is a schematic diagram of a substrate processing device according to one or more embodiments. FIG. 4 is a partially enlarged cross-sectional view of the substrate processing device according to one or more embodiments. The substrate processing device 1 shown in FIGS. 3 and 4 is a capacitively coupled plasma processing device. The substrate processing device 1 includes a first chamber 10, a second chamber 20 (inner chamber), and a substrate support 30.

The first chamber 10 has an internal space. The first chamber 10 is formed from a metal, such as aluminum. The first chamber 10 is electrically grounded. The first chamber 10 may have an anticorrosive film on its surface. The anticorrosive film is formed from, for example, a material, such as aluminum oxide (Al₂O₃) or yttrium oxide (Y₂O₃).

The first chamber 10 includes a side wall 10s. The side wall 10s is substantially cylindrical. The side wall 10s has a central axis extending in the vertical direction and indicated by an axis AX in FIG. 3. The side wall 10s has a port 10p. The internal space of the first chamber 10 is connected to the internal space of the transfer chamber TC in the transfer module TM with the port 10p. The port 10p is open and closed by a gate valve 10g. The substrate W is transferred between the internal space of the first chamber 10 and the outside of the first chamber 10 through the port 10p.

The side wall 10s further has openings 10o. The openings 10o are sized to allow the second chamber 20 to pass through. The internal space of the first chamber 10 is connectable to the internal space of the transfer module CTM through the openings 10o. The openings 10o are open and closed by a gate valve 10v.

In one or more embodiments, the side wall 10s partially has a double structure including an inner side wall 10i and an outer side wall 10e. The inner side wall 10i and the outer side wall 10e define a space 10q between them. The openings 10o are located in the inner side wall 10i and the outer side wall 10e. The gate valve 10v extends along the inner side wall 10i to open and close the openings 10o.

The first chamber 10 may further include an upper portion 10u. The upper portion 10u extends from an upper end of the side wall 10s in a direction intersecting with the axis AX. The upper portion 10u has an opening in an area intersecting with the axis AX.

The first chamber 10 further includes a movable unit 10m (e.g., movable housing). The movable unit 10m is located below the upper portion 10u in the first chamber 10 and inward from the side wall 10s. The movable unit 10m is movable vertically in the first chamber 10.

The substrate processing device 1 further includes a lifter 12. The lifter 12 vertically moves the movable unit 10m. The lifter 12 includes a drive 12d and a shaft 12s. The movable unit 10m is fixed to the shaft 12s. The shaft 12s extends upward from the movable unit 10m through the opening in the upper portion 10u. The drive 12d is located outside the first chamber 10. The drive 12d vertically moves the shaft 12s. The drive 12d may include, for example, a motor for moving the shaft 12s. The shaft 12s vertically moves to vertically move the movable unit 10m.

The substrate processing device 1 may further include a bellows 14. The bellows 14 is located between the movable unit 10m and the upper portion 10u. The bellows 14 separates the internal space of the first chamber 10 from the outside of the first chamber 10. The bellows 14 has its lower end fixed to the movable unit 10m and its upper end fixed to the upper portion 10u.

In one or more embodiments, the movable unit 10m may include a first member 10a and a second member 10b. The first member 10a and the second member 10b are fixed to each other. The first member 10a is substantially disk-shaped. The first member 10a may serve as an upper electrode in the substrate processing device 1. The second member 10b is substantially cylindrical. The second member 10b extends along the outer circumference of the first member 10a and above the first member 10a. The bellows 14 described above has its lower end fixed to the upper end of the second member 10b. The first member 10a and the second member 10b are formed from a conductor, such as aluminum. The first member 10a and the second member 10b may be electrically connected to the first chamber 10.

In one or more embodiments, the movable unit 10m may have a gas channel 10a1 connected to the gas supply 16. The gas supply 16 is external to the first chamber 10. The gas supply 16 includes one or more gas sources, one or more flow controllers, and one or more valves used in the substrate processing device 1. Each gas source is connected to the gas channel 10a1 through the corresponding flow controller and the corresponding valve. The gas channel 10a1 is defined in, for example, the first member 10a. A gas path 16a between the gas supply 16 to the gas channel 10a1 may extend inside the shaft 12s in an internal space of the bellows 14.

The substrate support 30 (substrate support) is located in the first chamber 10 and below the movable unit 10m. The substrate support 30 supports the substrate W received on the substrate support 30. The substrate support 30 may be supported by a support 31. The support 31 is substantially cylindrical. The support 31 is formed from an insulator, such as quartz. The support 31 may extend upward from a bottom plate 32. The bottom plate 32 may be formed from a metal, such as aluminum.

The substrate support 30 may include a lower electrode 34 and an electrostatic chuck (ESC) 36. The lower electrode 34 is substantially disk-shaped. The lower electrode 34 has its central axis substantially aligned with the axis AX. The lower electrode 34 is formed from a conductor, such as aluminum. The lower electrode 34 has an internal channel 34f. The channel 34f extends, for example, spirally. The channel 34f is connected to a chiller unit 35. The chiller unit 35 is located outside the first chamber 10. The chiller unit 35 supplies a refrigerant to the channel 34f. The refrigerant supplied to the channel 34f returns to the chiller unit 35.

The substrate processing device 1 may further include a first RF power supply 41 and a second RF power supply 42. The first RF power supply 41 generates first RF power. The first RF power has a frequency suitable for generating plasma. The first RF power has a frequency higher than or equal to, for example, 27 MHz. The first RF power supply 41 is electrically coupled to the lower electrode 34 through a matcher 41m. The matcher 41m includes a matching circuit for matching the impedance of a load (lower electrode 34) for the first RF power supply 41 and the output impedance of the first RF power supply 41. The first RF power supply 41 may be coupled to the upper electrode through the matcher 41m rather than to the lower electrode 34.

The second RF power supply 42 generates second RF power. The second RF power has a frequency suitable for drawing ions toward the substrate W. The second RF power has a frequency lower than or equal to, for example, 13.56 MHz. The second RF power supply 42 is electrically coupled to the lower electrode 34 through a matcher 42m. The matcher 42m includes a matching circuit for matching the impedance of a load (lower electrode 34) for the second RF power supply 42 and the output impedance of the second RF power supply 42.

The ESC 36 is located on the lower electrode 34. The ESC 36 includes a body and an electrode 36a. The body of the ESC 36 is substantially disk-shaped. The ESC 36 has a central axis substantially aligned with the axis AX. The body of the ESC 36 is formed from ceramic. The substrate W is placed on the upper surface of the body of the ESC 36. The electrode 36a is a film formed from a conductor. The electrode 36a is located in the body of the ESC 36. The electrode 36a is coupled to a direct current (DC) power supply 36d through a switch 36s. A DC voltage is applied from the DC power supply 36d to the electrode 36a to generate an electrostatic attraction between the ESC 36 and the substrate W. The electrostatic attraction causes the ESC 36 to attract and hold the substrate W. The substrate processing device 1 may have a gas line to supply a heat transfer gas (e.g., a helium gas) to a space between the ESC 36 and the back surface of the substrate W.

The substrate support 30 may support an edge ring ER placed on the substrate support 30. The substrate W is placed on the ESC 36 in an area surrounded by the edge ring ER. The edge ring ER is formed from, for example, silicon, quartz, or silicon carbide.

The substrate processing device 1 may further include an insulator 37. The insulator 37 is formed from an insulator, such as quartz. The insulator 37 may be substantially cylindrical. The insulator 37 extends along the outer peripheries of the lower electrode 34 and the ESC 36.

The substrate processing device 1 may further include a conductor 38. The conductor 38 is formed from a conductor, such as aluminum. The conductor 38 may be substantially cylindrical. The conductor 38 extends along the outer periphery of the substrate support 30. More specifically, the conductor 38 is located outward from the insulator 37 in the radial direction and extends in the circumferential direction. The radial direction and the circumferential direction refer to the directions with respect to the axis AX. The conductor 38 is grounded. In one example, the conductor 38 is grounded through the bottom plate 32 and the first chamber 10.

The substrate processing device 1 may further include a cover ring 39. The cover ring 39 is formed from an insulator, such as quartz. The cover ring 39 is annular. The cover ring 39 is located on the insulator 37 and the conductor 38 to be located radially outward from an area in which the edge ring ER is located.

The second chamber 20 is an inner chamber located in the first chamber 10 in the substrate processing device 1 and defining the processing space S together with the substrate support 30. The second chamber 20 is removable from the first chamber 10 and transferable between the internal space of the first chamber 10 and the outside of the first chamber 10 through the openings 10o.

The second chamber 20 in one or more embodiments includes a circulation space 20a, a supply port 20b, and outlets 20c. For example, the wall 21 of the second chamber 20 includes a ceiling 22 and a peripheral wall 23. The wall 21 may be formed from a material with a low conductivity, such as Si or SiC. The wall 21 may have a multilayer structure. For example, the surface of the wall 21 may be covered with a material (low contamination material) that is less likely to cause particles. In this case, the surface material may be aluminum oxide, yttrium oxide, silicon dioxide (SiO₂), silicon (Si), or silicon carbide (SiC). A substrate covered with the surface material may be formed from a material, such as aluminum (Al), tungsten (W), molybdenum (Mo), titanium (Ti), carbon, ceramic, silicon dioxide, silicon carbide, or other materials.

The ceiling 22 is a portion of the wall 21 facing the substrate support 30. The ceiling 22 is, for example, disk-shaped and may be supported by the movable unit 10m while being in contact with the lower surface of the movable unit 10m. The ceiling 22 includes contact members 25 on its upper surface. The contact members 25 are located between the upper surface of the ceiling 22 and the lower surface of the movable unit 10m and electrically connect the movable unit 10m and the ceiling 22. The contact members 25 are formed from a material having a volume resistivity lower than or equal to the volume resistivity of the material of the outer surface of the wall 21. In one example, multiple contact members 25 may be equally spaced in the circumferential direction about the axis AX. The contact members 25 electrically connect the wall 21 to the grounded movable unit 10m, forming a return path for RF waves.

The substrate processing device 1 further includes a clamp 50 and a releaser 60 to releasably fasten the ceiling 22 in the second chamber 20 to the first chamber 10. The clamp 50 is configured to releasably fasten the second chamber 20 to the first chamber 10. The releaser 60 releases the second chamber 20 fastened with the clamp 50.

As shown in FIGS. 3 and 4, the clamp 50 includes multiple supports 52 and multiple springs 54 in one or more embodiments. The clamp 50 may further include a plate 56. The clamp 50 may include a single support 52 and a single spring 54.

Each support 52 has a lower end 52b. The lower end 52b suspends the ceiling 22. The springs 54 urge the ceiling 22 toward the movable unit 10m in the first chamber 10.

In one or more embodiments, the movable unit 10m in the first chamber 10 has a cavity 10c. The cavity 10c may extend in the circumferential direction about the axis AX. The cavity 10 c is closed with a lid 58. The lid 58 is located on the movable unit 10m in the first chamber 10 to close the cavity 10 c. The movable unit 10m further has multiple holes 10t. The holes 10t may be arranged at equal intervals about the axis AX. The holes 10t extend downward from the cavity 10c and are open toward the ceiling 22. The ceiling 22 includes multiple recessed portions 20r. The recessed portions 20r are connected to the respective holes 10t when the second chamber 20 is fastened to the first chamber 10.

In one or more embodiments, the supports 52 are rods. The lower end 52b of each support 52 protrudes in the horizontal direction. Each recessed portion 20r has a bottom including an extension 20e. The extension 20e may receive the lower end 52b of the corresponding one of the multiple supports 52. In one example, each support 52 may be a screw and have the lower end 52b that is the head of the screw.

The supports 52 extend downward from the cavity 10c through the holes 10t. When the ceiling 22 is suspended from the supports 52, the lower ends 52b of the supports 52 are located in the respective recessed portions 20r and the extensions 20e in the recessed portions 20r.

The upper ends of the supports 52 are fixed to the plate 56 in the cavity 10c. The springs 54 are located in the cavity 10c. The springs 54 are located between the surface of the movable unit 10m defining the cavity 10c from below and the plate 56. In one or more embodiments, the springs 54 are coil springs. The springs 54 surround the supports 52 in the cavity 10c.

In one or more embodiments, the releaser 60 includes an air supply. The air supply applies an air pressure to separate the lower end 52b of each support 52 from the second chamber 20 to release the ceiling 22 fastened with the clamp 50. The air supply in the releaser 60 may supply air to a space between the lid 58 and the plate 56. When air is supplied to the space between the lid 58 and the plate 56, the plate 56 and the supports 52 move downward, separating the lower end 52b of each support 52 from the second chamber 20. Thus, the ceiling 22 fastened with the clamp 50 is released. When the ceiling 22 fastened with the clamp 50 is released, the second chamber 20 fastened to the first chamber 10 is released to allow the second chamber 20 to be transferred from the internal space of the first chamber 10 to the outside of the first chamber 10.

The peripheral wall 23 is continuous with the ceiling 22 and surrounds the substrate support 30. For example, the peripheral wall 23 includes a side portion 23a and a bottom portion 23b. The side portion 23a is cylindrical. The side portion 23a has an upper end connected to the periphery of the ceiling 22. The bottom portion 23b is annular. The bottom portion 23b has an outer edge connected to the lower end of the side portion 23a. As viewed in a direction along the axis AX, the bottom portion 23b has the outer edge aligned with the outer edge of the side portion 23a and an inner edge aligned with the outer edge of the conductor 38.

The bottom portion 23b may be electrically connected to a ground member that is grounded and surrounds the substrate support 30. In other words, the bottom portion 23b may be grounded. In one or more embodiments, the bottom portion 23b is electrically connected to the conductor 38 serving as the ground member. In the illustrated example, a contact 40 in the substrate processing device 1 electrically connects the bottom portion 23b to the conductor 38. This forms the return path for RF waves.

The contact 40 is electrically connected to the conductor 38. The bottom portion 23b is in contact with the contact 40 when defining the processing space S together with the substrate support 30. The processing space S is a space in which the substrate W is processed. In one or more embodiments, the contact 40 is located radially outward from the cover ring 39 and extends upward from the conductor 38.

The contact 40 may be elastically in contact with the bottom portion 23b. As shown in FIG. 4, the contact 40 may include a spring 40s. The contact 40 may further include a contact portion 40c. The spring 40s and the contact portion 40c are conductive. The spring 40s has its lower end fixed to the conductor 38. The spring 40s extends upward from the conductor 38. The contact portion 40c is fixed to the upper end of the spring 40s. The contact portion 40c is in contact with the bottom portion 23b. In the illustrated example, the bottom portion 23b has a groove for receiving the contact portion 40c.

The circulation space 20a is defined in the wall 21 of the second chamber 20 to allow a gas to circulate in a direction in which the wall 21 extends. The direction in which the wall 21 extends may be a direction in which the inner or outer surface of the wall 21 extends. In the second chamber 20 in one or more embodiments, the circulation space 20a extends in the ceiling 22 in a direction in which the ceiling 22 extends. The circulation space 20a in the ceiling 22 is substantially disk-shaped. The circulation space 20a extends in the side portion 23a in a direction in which the side portion 23a extends. The circulation space 20a in the side portion 23a is substantially cylindrical. The circulation space 20a extends in the bottom portion 23b in the direction in which the bottom portion 23b extends. The circulation space 20a in the bottom portion 23b is substantially annular. In one example, the wall 21 in the second chamber 20 may have a double structure including an inner wall 21a and an outer wall 21b to define the circulation space 20a. Although the circulation space 20a in the illustrated example extends in the direction in which the wall 21 extends, the circulation space 20a may be a set of tubular spaces.

The second chamber 20 includes the supply port 20b for supplying the gas to the circulation space 20a. The supply port 20b connects with the circulation space 20a and may be exposed outside the second chamber 20. In one or more embodiments, the second chamber 20 supported by the movable unit 10m has the supply port 20b connected to the gas channel 10a1 defined in the movable unit 10m. The second chamber 20 may include one or more supply ports 20b. For example, multiple supply ports 20b may be arranged at equal intervals in the circumferential direction about the axis AX. The supply port 20b in the illustrated example is located closer to the axis AX than the corresponding contact member 25 in the radial direction with respect to the axis AX. In one example, the supply port 20b in the second chamber 20 and the gas channel 10a1 in the movable unit 10m include fluid couplings (quick joints) corresponding to each other, and may connect with each other with the fluid couplings.

The outlets 20c connect with the circulation space 20a. The outlets 20c discharge the gas supplied through the supply port 20b to the circulation space 20a. In one or more embodiments, the second chamber 20 includes first outlets 20c1 that discharge the gas to the inside of the second chamber 20, and second outlets 20c2 that discharge the gas to the outside the second chamber 20. In other words, the first outlets 20c1 extend through the inner wall 21a of the wall 21, and the second outlets 20c2 extend through the outer wall 21b of the wall 21. For example, the ceiling 22 includes the first outlets 20c1 alone and includes no second outlets 20c2. The side portion 23a and the bottom portion 23b include the first outlets 20c1 and the second outlets 20c2. The second chamber 20 may include the first outlets 20c1 or the second outlets 20c2, or both.

The wall 21 in the second chamber 20 may have air vents 20d. The air vents 20d connect the inside and the outside of the second chamber 20. In one or more embodiments, the air vents 20d do not connect with the circulation space 20a. In other words, the air vents 20d and the circulation space 20a are separated from each other by partitions 21c. The partitions 21c are cylindrical to define the air vents 20d and connect the inner wall 21a and the outer wall 21b.

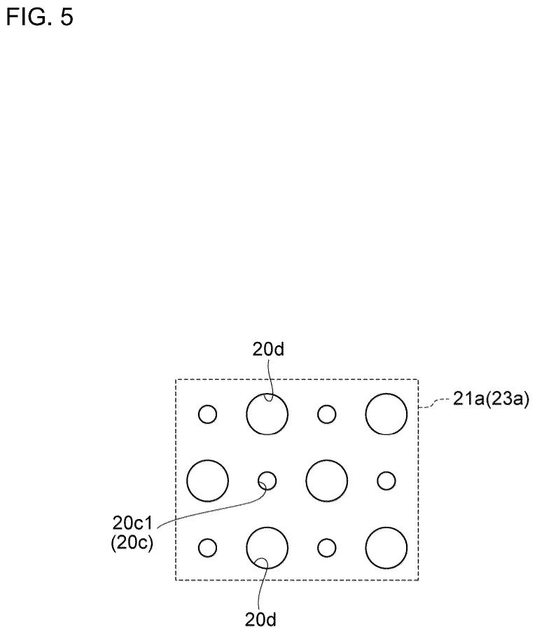

FIG. 5 is a schematic diagram of the side portion 23a of the second chamber 20 as viewed from inside the second chamber 20. As shown in FIG. 5, the air vents 20d in one example may be arranged in a staggered manner. For example, the side portion 23a includes the air vents 20d arranged at equal intervals in the vertical direction and the circumferential direction. The air vents 20d adjacent to each other in the vertical direction are arranged at circumferentially shifted positions. Each first outlet 20c1 is located between the adjacent air vents 20d arranged in a staggered manner. In other words, the first outlets 20c1 and the air vents 20d are arranged alternately in the circumferential direction and also in the vertical direction. The first outlets 20c1 and the second outlets 20c2 may be aligned with each other in the peripheral wall 23. In one example, the air vents 20d and the outlets 20c are both circular. The air vents 20d may have a larger diameter than the outlets 20c.

The substrate processing device 1 may further include an exhaust device 70. The exhaust device 70 includes a pressure regulator, such as an automatic pressure control valve and a decompression pump, such as a turbomolecular pump. The exhaust device 70 is connected to the bottom of the first chamber 10 below the bottom portion 23b.

A method for removing the second chamber 20 will now be described. The second chamber 20 may be removed from the first chamber 10 and transferred from the internal space of the first chamber 10 to the internal space of the chamber 110 in the transfer module CTM for, for example, maintenance. The controller MC may control the operation of the substrate processing device 1. The controller 140 may control the operation of the transfer module CTM. The controller 140 may control the transfer module CTM based on information, such as a command transmitted from the controller MC.

In one example, the transfer module CTM is first moved to connect the chamber 110 in the transfer module CTM to the first chamber 10 in the substrate processing device 1. When the chamber 110 is connected to the first chamber 10, the side wall 10s, the gate valve 10v, the side wall 110s, and the gate valve 116 define a sealed space. The sealed space includes the space 10q and the space 110q. The sealed space is decompressed by the exhaust device 122. At the same time, the internal space 112 of the chamber 110 in the transfer module CTM is also decompressed by the exhaust device 122.

The gate valve 10v and the gate valve 116 then move to connect the internal space of the first chamber 10 and the internal space 112 of the chamber 110 in the transfer module CTM. The lifter 12 then separates the movable unit 10m and the second chamber 20 upward from the substrate support 30 in the first chamber 10. The arm 120a in the transfer unit 120 then enters the internal space of the first chamber 10 to extend to a portion below the second chamber 20. The lifter 12 moves the movable unit 10m and the second chamber 20 downward to place the second chamber 20 on the arm 120a. The releaser 60 then releases the second chamber 20 fastened with the clamp 50. The transfer unit 120 moves the second chamber 20 in the horizontal direction to retract the lower ends 52b of the supports 52 from the extensions 20e. The lifter 12 then moves the movable unit 10m upward to separate the movable unit 10m from the second chamber 20. This moves the lower ends 52b of the supports 52 out of the recessed portions 20r. The arm 120a in the transfer unit 120 then moves the second chamber 20 from the internal space of the first chamber 10 to the internal space 112 of the chamber 110 in the transfer module CTM through the openings 10o and the openings 110o. The gate valves 10v and 116 then move to close the openings 10o and the openings 110o.

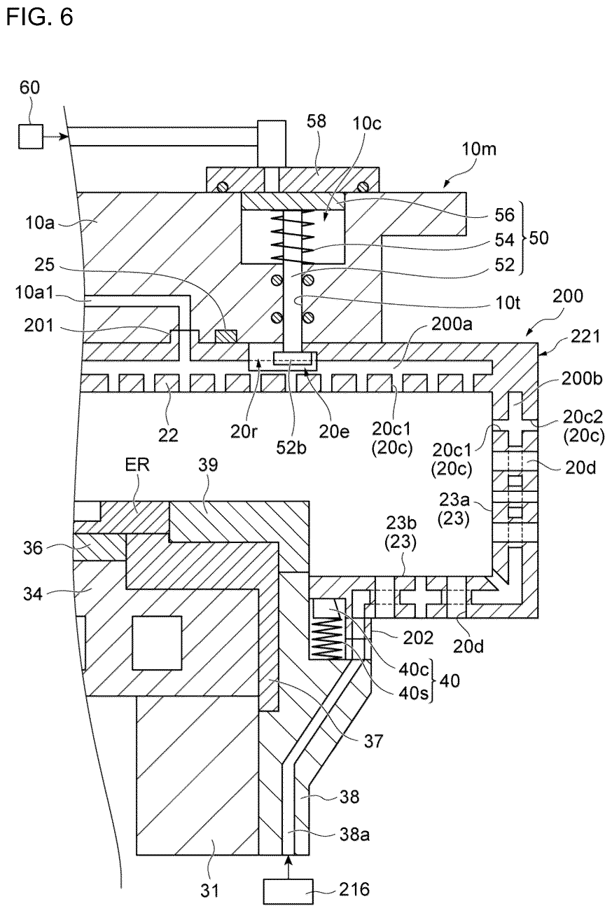

FIG. 6 is a cross-sectional view of a second chamber in one or more embodiments. The structures not described below and not shown in the figure may be the same as the structures of the second chamber 20 shown in, for example, FIG. 4. The second chamber 200 in one or more embodiments includes a first circulation space 200a, a second circulation space 200b, the outlets 20c, and the air vents 20d. The second chamber 200 includes a wall 221 including the ceiling 22 and the peripheral wall 23, similarly to the second chamber 20.

The first circulation space 200a and the second circulation space 200b are defined in the wall 221 of the second chamber 200 to allow a gas to circulate in a direction in which the wall 221 extends. The first circulation space 200a extends in the ceiling 22 in the direction in which the ceiling 22 extends. The second circulation space 200b extends in the peripheral wall 23 in a direction in which the peripheral wall 23 extends. In other words, the second circulation space 200b extends in the side portion 23a in the direction in which the side portion 23a extends, and extends in the bottom portion 23b in a direction in which the bottom portion 23b extends. The first circulation space 200a and the second circulation space 200b do not connect with each other and are divided from each other. The first circulation space 200a may connect with the first outlets 20c1. The second circulation space 200b may connect with the first outlets 20c1 and the second outlets 20c2. The peripheral wall 23 may have the air vents 20d, similarly to the second chamber 20.

The second chamber 200 includes a first supply port 201 for supplying a gas to the first circulation space 200a and a second supply port 202 for supplying a gas to the second circulation space 200b. The first supply port 201 may have the same structure as the supply port 20b in the second chamber 20.

The second supply port 202 connects with the second circulation space 200b and is exposed outside on the peripheral wall 23. In one or more embodiments, the second supply port 202 is connected to a gas discharge channel 38a in the conductor 38. The second chamber 200 may include one or more second supply ports 202. For example, multiple second supply ports 202 may be arranged at equal intervals in the circumferential direction about the axis AX. For example, the gas discharge channel 38a extends in the conductor 38 and opens at a position outward from the contact 40 in the radial direction about the axis AX. In one example, the second supply port 202 and the gas discharge channel 38a include fluid couplings corresponding to each other, and may connect with each other with the fluid couplings.

The gas discharge channel 38a connected to the second supply port 202 may be connected to another gas supply 216 other than the gas supply 16. The gas supply 216 includes one or more gas sources, one or more flow controllers, and one or more valves used in the substrate processing device 1. Each gas source is connected to the gas discharge channel 38a through the corresponding flow controller and the corresponding valve. For example, the gas supplies 16 and 216 may supply different gases to the first supply port 201 and the second supply port 202.

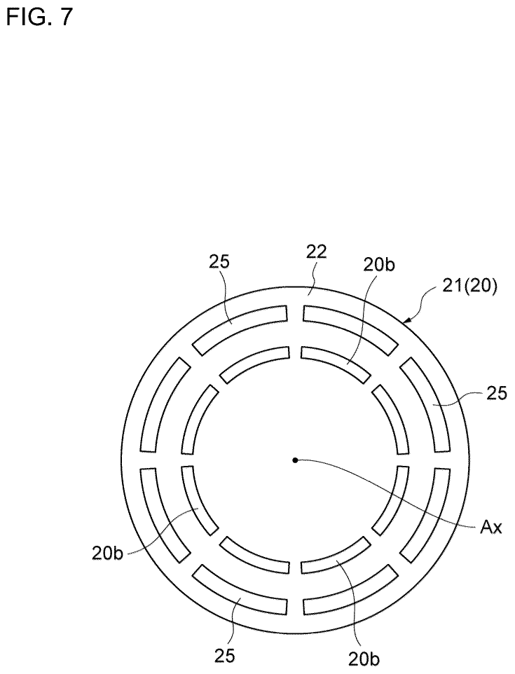

FIG. 7 is a schematic diagram of supply ports in a second chamber in a substrate processing device according to one or more embodiments. FIG. 7 is a schematic plan view of the ceiling 22 included in the wall 21 as viewed from above, describing the structures of the supply ports 20b and the contact members 25 in the second chamber 20 in one or more embodiments. As shown in FIG. 7, the supply ports 20b are arc-shaped and may be arranged on the circumference about the axis AX. Similarly, the contact members 25 are arc-shaped and may be arranged on the circumference about the axis AX. In the illustrated example, the contact members 25 are located radially outward from the supply ports 20b with respect to the axis AX. For example, a space between the supply ports 20b and the gas channel 10a1 may be sealed with a sealing member, such as an O-ring. The multiple supply ports 20b arranged on the circumference may be connected to one another to form a single annular supply port.

As described above, the substrate processing device 1 according to one or more embodiments includes the first chamber 10 and the second chamber 20. In the first chamber 10, the substrate support 30 to receive the substrate W is located. The second chamber 20 is located in the first chamber 10. The second chamber 20 defines, together with the substrate support 30, the processing space S for processing the substrate W received on the substrate support 30. The second chamber 20 includes the circulation space 20a, the supply port 20b, and the outlets 20c. The circulation space 20a is defined in the wall 21 of the second chamber 20 to allow a gas to circulate in a direction in which the wall 21 extends. The supply port 20b connects with the circulation space 20a to supply the gas. The outlets 20c connect with the circulation space 20a and discharge the gas to at least one of the inside or the outside of the second chamber 20.

For example, in a structure including the gas holes vertically extending through the second chamber and the movable unit supporting the second chamber, gas outlet ports in the second chamber are limited to be in an area in which the second chamber is in contact with the movable unit. In the substrate processing device 1 according to one or more embodiments, the gas supplied through the supply port 20b passes through the circulation space 20a in the wall 21 of the second chamber 20 and is discharged through the outlets 20c. With the circulation space 20a extending in the direction in which the wall 21 extends, the outlets 20c can be at any positions in the wall 21. In this structure, the outlets 20c can be at any positions independently of the position of the supply port 20b for the gas. Thus, the outlets 20c can be arranged in a larger area in the radial direction of the chamber.

In one or more embodiments, the wall 221 of the second chamber 200 may include the ceiling 22 facing the substrate support 30 and the peripheral wall 23 continuous with the ceiling 22 and surrounding the substrate support 30. The circulation space 20a may be divided into the first circulation space 200a extending in the ceiling 22 in the direction in which the ceiling 22 extends and the second circulation space 200b extending in the peripheral wall 23 in the direction in which the peripheral wall 23 extends. The second chamber 200 may include the first supply port 201 connecting with the first circulation space 200a and the second supply port 202 connecting with the second circulation space 200b. This structure includes the circulation space 20a divided into the first circulation space 200a and the second circulation space 200b, and thus can supply gases with different flow rates to the first circulation space 200a and the second circulation space 200b.

In one or more embodiments, different gases are supplied to the first supply port 201 and the second supply port 202. This structure allows the different gases to be discharged as intended to a space near the outlets 20c in the ceiling 22 and to a space near the outlets 20c in the peripheral wall 23.

In one or more embodiments, the outlets 20c include the first outlets 20c1 that are open to the inside of the second chamber 20 and the second outlets 20c2 that are open to the outside of the second chamber 20. In this structure, the gas discharged through the first outlets 20c1 facing the inside of the second chamber 20 can reduce deposit accumulated on the inner wall of the second chamber 20. The gas discharged from the second outlets 20c2 facing the outside of the second chamber 20 can reduce deposit accumulated on the inner wall of the first chamber 10.

In one or more embodiments, the peripheral wall 23 has the air vents 20d connecting the inside and the outside of the second chamber 20. The air vents 20d and the circulation space 20a may be separated by the partitions 21c. The air vents 20d are arranged in a staggered manner. Each outlet 20c is located between the adjacent air vents 20d and faces the inside of the second chamber 20. In this structure, the gas discharged through the outlets 20c moves along the inner wall of the second chamber 20 before being discharged through the air vents 20d to outside the second chamber 20. In this case, the gas may protect the inner wall of the second chamber 20 as an air curtain.

In one or more embodiments, the gas from the gas supply 16 is supplied to the supply port 20b through the space defined by the bellows 14. This structure easily provides the path for supplying the gas.

Although various exemplary embodiments have been described above, the embodiments are not restrictive, and various additions, omissions, substitutions, and changes may be made. The components in the different embodiments may be combined to form another embodiment.

In another embodiment, for example, the substrate processing device may be of another type,, such as an inductively coupled plasma processing device, an electron cyclotron resonance (ECR) plasma processing device, or a plasma processing device that generates plasma using microwaves. In still another embodiment, the substrate processing device may perform substrate processing other than plasma processing.

Although the clamp 50 supports the second chamber in the above structure, for example, the second chamber may include a protrusion protruding upward, and the movable unit 10m may support the protrusion. Although the contact 40 is electrically in contact with the second member in the above structure, for example, the second chamber 20 may include a contact on the bottom portion 23b, and the conductor 38 may include a recessed portion for receiving the contact.

Although the gas path 16a connecting the gas supply 16 and the gas channel 10a1 extends through inside the shaft 12s in the space defined by the bellows, the path may have a different structure. For example, two bellows with different diameters may be arranged concentrically to define a space for a gas path between them.

Although the contact members 25 electrically connect the movable unit 10m and the second chamber 20 in the above example, the clamp 50 may serve as a contact member.

Various exemplary embodiments according to the disclosure have been described by way of example, and various changes may be made without departing from the scope and spirit of the disclosure. One or more embodiments disclosed above are thus not restrictive, and the true scope and spirit of the disclosure are defined by the appended claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

Various exemplary embodiments included in the disclosure will now be described.
E1

A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes
   a circulation space defined in a wall of the second chamber to allow a gas to circulate in a direction in which the wall extends,
   at least one supply port connecting with the circulation space to supply the gas, and
   at least one outlet connecting with the circulation space to discharge the gas to at least one of an inside or an outside of the second chamber.
E2

The substrate processing device according to E1, wherein
the wall of the second chamber includes a ceiling facing the substrate support and a peripheral wall continuous with the ceiling and surrounding the substrate support,
the circulation space is divided into a first circulation space extending in the ceiling in a direction in which the ceiling extends and a second circulation space extending in the peripheral wall in a direction in which the peripheral wall extends, and
the at least one supply port includes a first supply port connecting with the first circulation space and a second supply port connecting with the second circulation space.
E3

The substrate processing device according to E2, wherein
the first supply port and the second supply port are supplied with different gases.
E4

The substrate processing device according to E1, wherein
the at least one outlet includes a first outlet open to the inside of the second chamber and a second outlet open to the outside of the second chamber.
E5

The substrate processing device according to E2 or E3, wherein
the peripheral wall has air vents separated from the circulation space by partitions and connecting the inside and the outside of the second chamber,
the air vents are arranged in a staggered manner, and
the at least one outlet is located between adjacent air vents of the air vents and faces the inside of the second chamber.
E6

The substrate processing device according to any one of E1 to E5, further comprising:
a movable housing configured to vertically move the second chamber in the first chamber; and
a bellows connected to the movable housing and separating a space in the first chamber from an outside of the first chamber,
wherein the gas is supplied to the at least one supply port through inside a space defined by the bellows.
E7

The substrate processing device according to E1, wherein
the wall of the second chamber includes:
a ceiling facing the substrate support; and
a peripheral wall continuous with the ceiling and surrounding the substrate support,
the circulation space is divided into a first circulation space extending in the ceiling in a direction in which the ceiling extends and a second circulation space extending in the peripheral wall in a direction in which the peripheral wall extends.
E8

The substrate processing device according to E7, wherein the first circulation space and the second circulation space are not connected to one another and are divided from each other.
E9

The substrate processing device according to E8, wherein
the at least one outlet includes:
a plurality of first outlets open to the inside of the second chamber; and
a plurality of second outlets open to the outside of the second chamber, and
the plurality of first outlets include a first group of first outlets connected to the first circulation space and a second group of first outlets connected to the second circulation space.
E10

The substrate processing device according to E9, wherein the second circulation space is further connected to the plurality of second outlets.
E11

A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes:
   a ceiling facing the substrate support;
a peripheral wall continuous with the ceiling and surrounding the substrate support;
a first circulation space extending in the ceiling in a direction in which the ceiling extends; and
a second circulation space extending in the peripheral wall in a direction in which the peripheral wall extends.
E12

The substrate processing device according to E11, wherein the second chamber further includes:
at least one supply port connecting with the first circulation space and the second circulation space to supply a gas; and
at least one outlet connecting with the first circulation space and the second circulation space to discharge the gas to at least one of an inside or an outside of the second chamber.
E13

The substrate processing device according to E12, the at least one supply port includes:
a first supply port connecting with the first circulation space; and
a second supply port connecting with the second circulation space.
E14

The substrate processing device according to E12, wherein
the at least one outlet includes:
a first outlet open to the inside of the second chamber; and
a second outlet open to the outside of the second chamber.
E15

The substrate processing device according to E12, wherein
the peripheral wall has air vents separated from the second circulation space by partitions, the air vents connecting the inside and the outside of the second chamber,
the air vents are arranged in a staggered manner, and
the at least one outlet is located between adjacent air vents of the air vents and the at least one outlet faces the inside of the second chamber
E16

The substrate processing device according to E12, further comprising:
a movable housing configured to vertically move the second chamber in the first chamber; and
a bellows connected to the movable housing and separating a space in the first chamber from an outside of the first chamber,
wherein the gas is supplied to the at least one supply port through inside a space defined by the bellows.
E17

The substrate processing device according to E11, wherein the first circulation space and the second circulation space are not connected to one another and are divided from each other.
E18

A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes:
a ceiling facing the substrate support;
a peripheral wall continuous with the ceiling and surrounding the substrate support;
a first circulation space extending in the ceiling in a direction in which the ceiling extends;
a second circulation space extending in the peripheral wall in a direction in which the peripheral wall extends;
at least one supply port connecting with the first circulation space and the second circulation space to supply the gas; and
at least one outlet connecting with the first circulation space and the second circulation space to discharge the gas to at least one of an inside or an outside of the second chamber.
E19

The substrate processing device according to E18, the at least one supply port includes:
a first supply port connecting with the first circulation space; and
a second supply port connecting with the second circulation space.
E20

The substrate processing device according to claim 19, wherein
the at least one outlet includes:
a first outlet open to the inside of the second chamber; and
a second outlet open to the outside of the second chamber.

### Reference Signs List

1 Substrate processing device
10 First chamber
20 Second chamber (inner chamber)
20a Circulation space
20b Supply port
20c Outlet
21 Wall
30 Substrate support
W Substrate

1. A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes:
a circulation space defined in a wall of the second chamber to allow a gas to circulate in a direction in which the wall extends;
at least one supply port connecting with the circulation space to supply the gas; and
at least one outlet connecting with the circulation space to discharge the gas to at least one of an inside or an outside of the second chamber.

2. The substrate processing device according to claim 1, wherein
the wall of the second chamber includes:
a ceiling facing the substrate support; and
a peripheral wall continuous with the ceiling and surrounding the substrate support,
the circulation space is divided into a first circulation space extending in the ceiling in a direction in which the ceiling extends and a second circulation space extending in the peripheral wall in a direction in which the peripheral wall extends, and
the at least one supply port includes:
a first supply port connecting with the first circulation space; and
a second supply port connecting with the second circulation space.

3. The substrate processing device according to claim 2, wherein the first supply port and the second supply port are to be supplied with different gases.

4. The substrate processing device according to claim 1, wherein
the at least one outlet includes:
a first outlet open to the inside of the second chamber; and
a second outlet open to the outside of the second chamber.

5. The substrate processing device according to claim 2, wherein
the peripheral wall has air vents separated from the circulation space by partitions, the air vents connecting the inside and the outside of the second chamber,
the air vents are arranged in a staggered manner, and
the at least one outlet is located between adjacent air vents of the air vents and the at least one outlet faces the inside of the second chamber.

6. The substrate processing device according to claim 1, further comprising:
a movable housing configured to vertically move the second chamber in the first chamber; and
a bellows connected to the movable housing and separating a space in the first chamber from an outside of the first chamber,
wherein the gas is supplied to the at least one supply port through inside a space defined by the bellows.

7. The substrate processing device according to claim 1, wherein
the wall of the second chamber includes:
a ceiling facing the substrate support; and
a peripheral wall continuous with the ceiling and surrounding the substrate support,
the circulation space is divided into a first circulation space extending in the ceiling in a direction in which the ceiling extends and a second circulation space extending in the peripheral wall in a direction in which the peripheral wall extends.

8. The substrate processing device according to claim 7, wherein the first circulation space and the second circulation space are not connected to one another and are divided from each other.

9. The substrate processing device according to claim 8, wherein
the at least one outlet includes:
a plurality of first outlets open to the inside of the second chamber; and
a plurality of second outlets open to the outside of the second chamber, and
the plurality of first outlets include a first group of first outlets connected to the first circulation space and a second group of first outlets connected to the second circulation space.

10. The substrate processing device according to claim 9, wherein the second circulation space is further connected to the plurality of second outlets.

11. A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes:
a ceiling facing the substrate support;
a peripheral wall continuous with the ceiling and surrounding the substrate support;
a first circulation space extending in the ceiling in a direction in which the ceiling extends; and
a second circulation space extending in the peripheral wall in a direction in which the peripheral wall extends.

12. The substrate processing device according to claim 11, wherein the second chamber further includes:
at least one supply port connecting with the first circulation space and the second circulation space to supply a gas; and
at least one outlet connecting with the first circulation space and the second circulation space to discharge the gas to at least one of an inside or an outside of the second chamber.

13. The substrate processing device according to claim 12, the at least one supply port includes:
a first supply port connecting with the first circulation space; and
a second supply port connecting with the second circulation space.

14. The substrate processing device according to claim 12, wherein
the at least one outlet includes:
a first outlet open to the inside of the second chamber; and
a second outlet open to the outside of the second chamber.

15. The substrate processing device according to claim 12, wherein
the peripheral wall has air vents separated from the second circulation space by partitions, the air vents connecting the inside and the outside of the second chamber,
the air vents are arranged in a staggered manner, and
the at least one outlet is located between adjacent air vents of the air vents and the at least one outlet faces the inside of the second chamber

16. The substrate processing device according to claim 12, further comprising:
a movable housing configured to vertically move the second chamber in the first chamber; and
a bellows connected to the movable housing and separating a space in the first chamber from an outside of the first chamber,
wherein the gas is supplied to the at least one supply port through inside a space defined by the bellows.

17. The substrate processing device according to claim 11, wherein the first circulation space and the second circulation space are not connected to one another and are divided from each other.

18. A substrate processing device, comprising:
a first chamber in which a substrate support to receive a substrate is located; and
a second chamber located in the first chamber, the second chamber defining, together with the substrate support, a processing space for processing the substrate received on the substrate support,
wherein the second chamber includes:
a ceiling facing the substrate support;
a peripheral wall continuous with the ceiling and surrounding the substrate support;
a first circulation space extending in the ceiling in a direction in which the ceiling extends;
a second circulation space extending in the peripheral wall in a direction in which the peripheral wall extends;
at least one supply port connecting with the first circulation space and the second circulation space to supply a gas; and
at least one outlet connecting with the first circulation space and the second circulation space to discharge the gas to at least one of an inside or an outside of the second chamber.

19. The substrate processing device according to claim 18, the at least one supply port includes:
a first supply port connecting with the first circulation space; and
a second supply port connecting with the second circulation space.

20. The substrate processing device according to claim 19, wherein the at least one outlet includes:
a first outlet open to the inside of the second chamber; and
a second outlet open to the outside of the second chamber.
